(19) United States
(12) Patent Application Publication
(10) Pub. No.: US 2008/0054982 A1
(43) Pub. Date: Mar. 6, 2008

(54) Low power level shifter and method thereof

(75) Inventor: Young-Chul Rhee, Yongin-si (KR)

Correspondence Address: LEE & MORSE, P.C., 3141 FAIRVIEW PARK DRIVE, SUITE 500, FALLS CHURCH, VA, 22042, US

(73) Assignee: Samsung Electronics Co., Ltd.,

(21) Appl. No.: 11/892,955

(22) Filed: Aug. 28, 2007

(30) Foreign Application Priority Data
Aug. 28, 2006 (KR) 10-2006-0081457

(51) Int. Cl. H03K 19/0175; H03K 19/0185

(52) U.S. Cl. 327/333

(57) ABSTRACT

Example embodiments relate to a low power level shifter. The low power level shifter may include an input unit, a pull-down driving unit, a pull-up driving unit and a blocking unit. The input unit may be configured to generate a current signal based on an input signal applied to an input port, so that the input signal may switch between a first voltage level and a second voltage level. The pull-down driving unit may be connected to an output port, the pull-up driving unit may be between a power supply voltage having a third voltage level and the output port, and the blocking unit may be between the input unit and the pull-up driving unit.

### BACKGROUND OF THE INVENTION

1. Field of the Invention

Example embodiments relate to a semiconductor device, and a method thereof, and more particularly, to a semiconductor device including a level shifter and a method thereof.

2. Description of the Related Art

Generally, a semiconductor integrated circuit (IC) may include components, e.g., circuit blocks, to perform functions of the IC, and components to externally interface with other circuits. Further, various source voltages may be required for the various circuit blocks. For example, most circuit blocks in the IC may operate using source voltages below 1.2V, whereas analog circuit blocks that interface with external circuits may operate using source voltages, such as 3.3V or 2.5V. Therefore, a level shifter may be required to interface between the circuit blocks using different source voltages.

Further, a direct current (DC) path may exist in a conventional level shifter, which may use a typical current mirror, and thus, a power loss may occur. Accordingly, a level shifter capable of operating at low power may be required.

### SUMMARY OF THE INVENTION

Example embodiments are therefore directed to a level shifter, and a method thereof, which substantially overcome one or more of the problems due to the limitations and disadvantages of the related art.

It is therefore a feature of an example embodiment to provide a level shifter capable of performing a level shifting operation safely at low power by blocking a current path during the level shifting operation.

It is therefore a feature of an example embodiment to provide a method of performing low power level shifting by safely operating a level shifter at low power by blocking a current path during the level shifting operation.

At least one of the above and other features of example embodiments may provide a low power level shifter having an input unit, a pull-down driving unit, a pull-up driving unit and a blocking unit. The input unit may be configured to generate a current signal based on an input signal applied to an input port, so that the input signal may switch between a first voltage level and a second voltage level. The pull-down driving unit may be connected to an output port, and may be configured to pull-down the output port to the first voltage level. The pull-up driving unit may be between a power supply voltage having a third voltage level and the output port, and may be configured to pull-up the output port to the third voltage level by mirroring the current signal. The blocking unit may be between the input unit and the pull-up driving unit, and may be configured to block a current path formed between the input unit and the pull-up driving unit in response to a pulling-up operation of the output port.

The low power level shifter may further include an inverter configured to invert the input signal to the pull-down driving unit. The inverter may operate between the first voltage level and the second voltage level.

The input unit may include a first n-type metal oxide semiconductor (NMOS) transistor having a gate that receives the input signal, a source connected to a ground voltage corresponding to the second voltage level, and a drain connected to the blocking unit. The pull-down driving unit may include a second NMOS transistor having a gate that receives the inverted input signal, a source connected to the ground voltage, and a drain connected to the output port.

The blocking unit may include a first p-type metal oxide semiconductor (PMOS) transistor and a second PMOS transistor to form a latch. The first PMOS transistor may have a gate connected to the output port and a drain of the second PMOS transistor, a source connected to the pull-up driving unit, and a drain that may receive the current from the input unit from the drain of the first NMOS transistor. The second PMOS transistor may have a gate connected to the drain of the first PMOS transistor and may receive the current from the input unit, a source connected to the source voltage, and the drain that may be connected to the output port and the gate of the first PMOS transistor. The current path between the input unit and the pull-up driving unit may be blocked by the first PMOS transistor.

The pull-up driving unit may include a current mirror having a third PMOS transistor and a fourth PMOS transistor. The third PMOS transistor may have a gate and a drain that may be commonly connected to a gate of the fourth PMOS transistor and may be connected to the source of the first PMOS transistor included in the blocking unit, and a source connected to the source voltage. The fourth PMOS transistor having the gate may be connected to the gate of the third PMOS transistor, a source connected to the source voltage, and a drain connected to the output port.

The third voltage may be higher than the first voltage, and the first voltage may be higher than the second voltage.

At least one of the above and other features of example embodiments may provide a low power level shifter, include a first NMOS transistor, a second NMOS transistor, a first PMOS transistor, a second PMOS transistor, a third PMOS transistor, and a fourth PMOS transistor. The first NMOS transistor may have a gate that receives an input signal. The second NMOS transistor may have a gate that receives an inverted input signal, a source connected to a ground voltage and a source of the first NMOS transistor, and a drain connected to an output port that outputs an output signal. The first PMOS transistor may have a drain that may be connected to a drain of the first NMOS transistor. The second PMOS transistor may have a gate that may be connected to the drain of the first PMOS transistor, and a drain connected to the output port and to a gate of the first PMOS transistor. The third PMOS transistor may have a gate and a drain that may be commonly connected to the source of the first PMOS transistor, and a source connected to a source voltage. The fourth PMOS transistor may have a gate that may be connected to the gate of the third PMOS transistor, a source connected to the source voltage, and a drain connected to the output port, the second PMOS transistor has a source that may be connected to the source voltage.

The inverter may be connected between the gate of the first NMOS transistor and the gate of the second NMOS transistor. The inverter may operate between a first voltage and the ground voltage. The source voltage may be higher than the first voltage.

The input signal may switch between a first voltage and the ground voltage, and the output signal switches between the source voltage and the ground voltage. The source voltage may be higher than the first voltage.

At least one of the above and other features of example embodiments may provide a method of low power level shifting. The method may include generating a current according to an input signal that switches between a first voltage and a second voltage, pulling-down an output port to the first voltage according to an inverted input signal, pulling-up the output port to a third voltage by mirroring the current, and blocking a current path that may be generated when the output port is pulled-up.

### BRIEF DESCRIPTION OF THE DRAWINGS

The above and other features and advantages of example embodiments will become more apparent to those of ordinary skill in the art by describing in detail example embodiments thereof with reference to the attached drawings, in which:

FIG. 1 illustrates a circuit diagram of a first level shifter using a current mirror;

FIG. 2 illustrates a circuit diagram of a second level shifter blocking a current path in FIG. 1;

FIG. 3 illustrates a circuit diagram of a low power level shifter according to an example embodiment;

FIG. 4 illustrates a diagram of an input voltage level of an input signal and an output voltage level of an output signal in a low power level shifter according to an example embodiment;

FIG. 5A illustrates a diagram of output voltages output from the level shifters in FIG. 1 through FIG. 3 when the output voltages transit from a low state to a high state;

FIG. 5B illustrates a diagram of output voltages output from the level shifters in FIG. 1 through FIG. 3 when the output voltages transit from a high state to a low state;

FIG. 5C illustrates a diagram of operation currents generated at the level shifters in FIG. 1 through FIG. 3 when the output voltages transit from a low state to a high state; and

FIG. 5D illustrates a diagram of operation currents generated at the level shifters in FIG. 1 through FIG. 3 when the output voltages transit from a high state to a low state.

### DETAILED DESCRIPTION OF THE INVENTION

Korean Patent Application No. 10-2006-0081457, filed on Aug. 28, 2006 in the Korean Intellectual Property Office, and entitled: “Low Power Level Shifter and Method of Low Power Level Shifting,” is incorporated by reference herein in its entirety.

Example embodiments will now be described more fully hereinafter with reference to the accompanying drawings. The invention may, however, be embodied in different forms and should not be construed as limited to the embodiments set forth herein. Rather, these example embodiments are provided so that this disclosure will be thorough and complete, and will fully convey the scope of the invention to those skilled in the art.

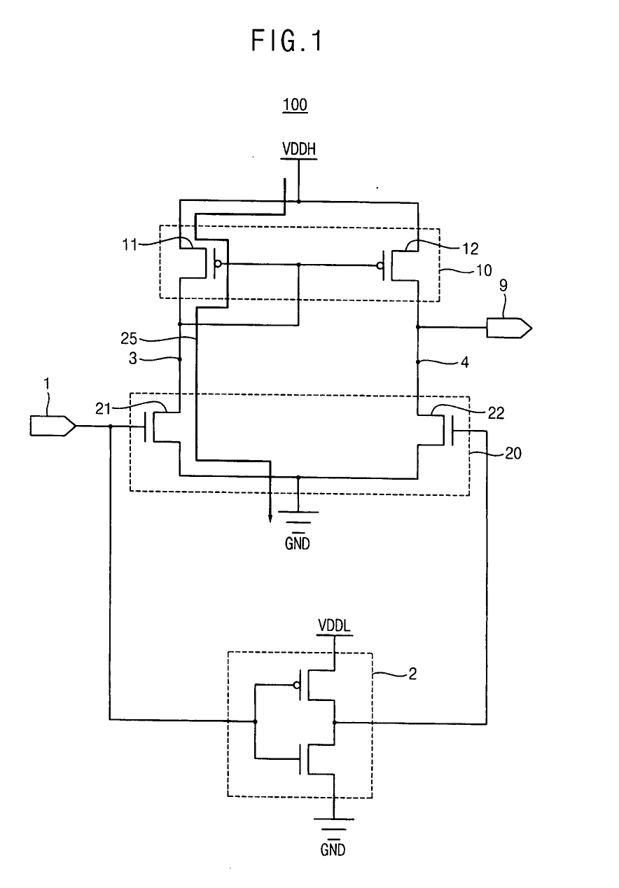

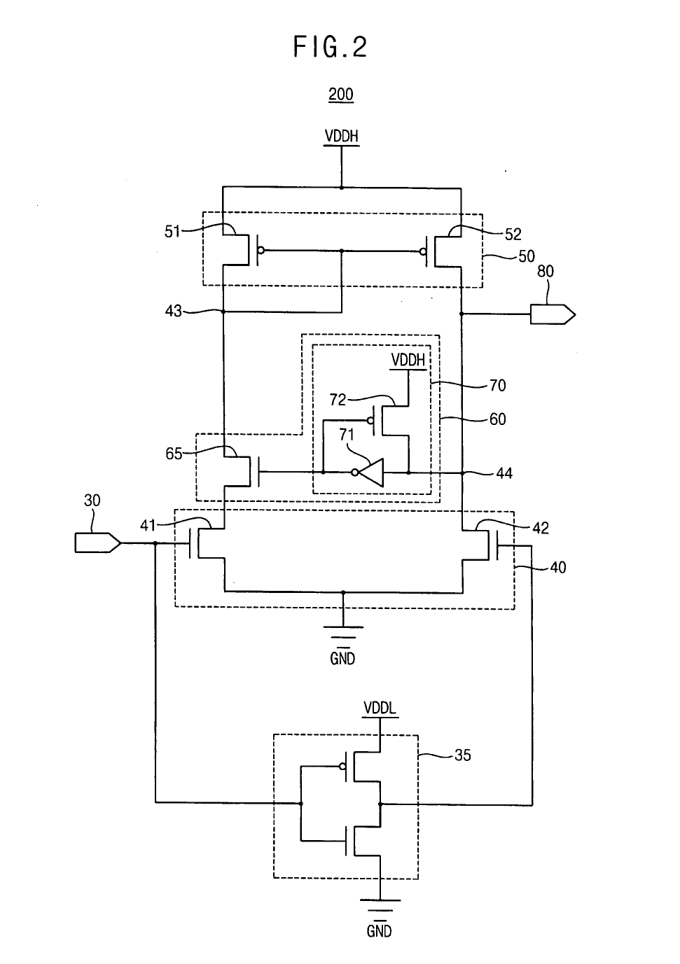

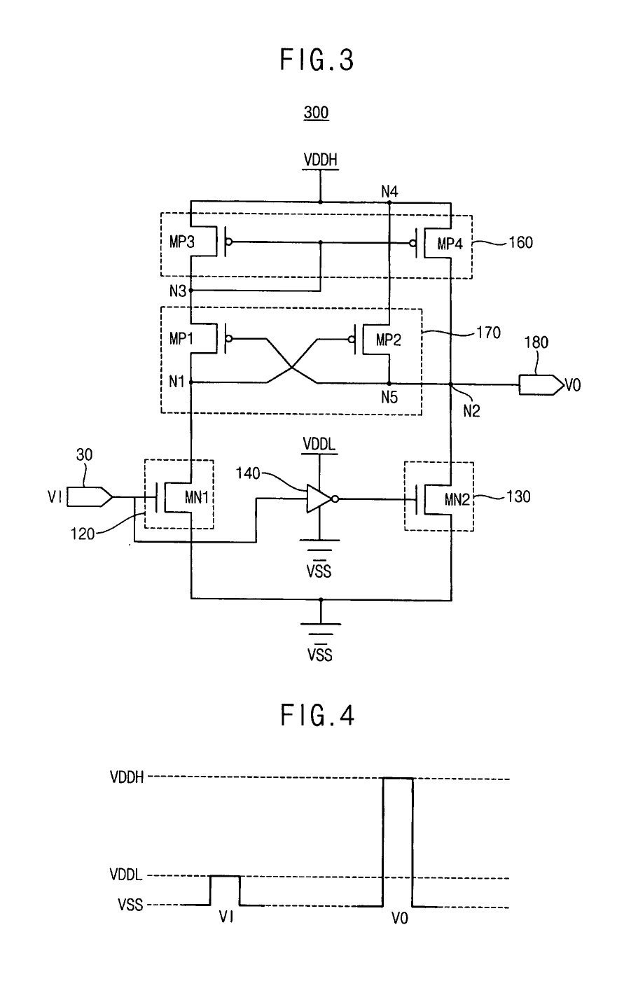

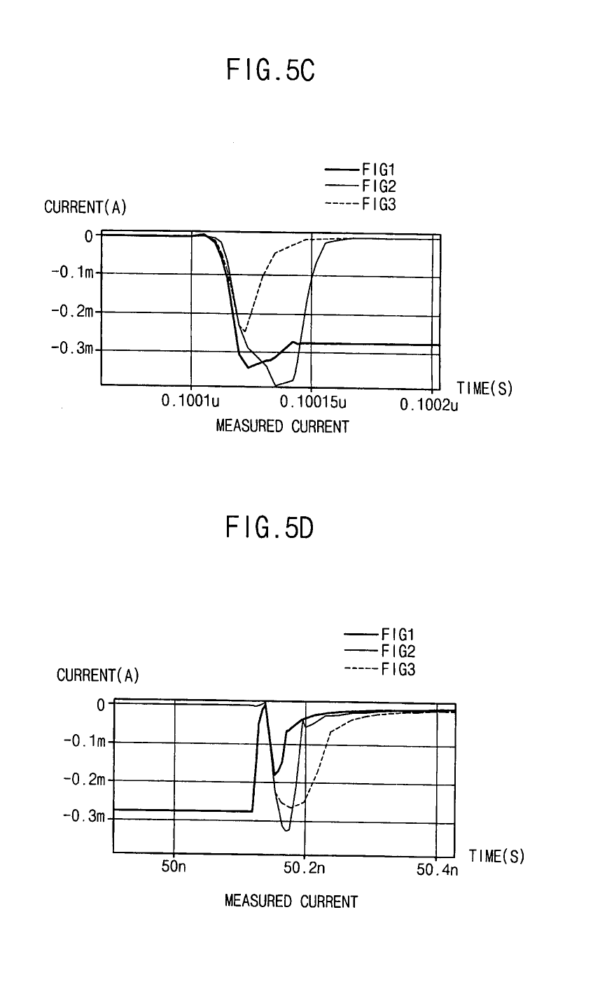

As will be fully described herein, FIGS. 1 through 3 describe various level shifters so as to compare (as illustrated in FIGS. 5A-5D) output voltages output and operation currents generated at the level shifters. FIGS. 1 and 2 will be used as comparative examples, and FIG. 3 illustrates an embodiment according to example embodiments.

FIG. 1 illustrates a circuit diagram of a first level shifter 100 using a current mirror.

Referring to FIG. 1, the first level shifter 100 may include a current mirror 10, an input unit 20, an input port 1, an inverter 2, and an output port 9.

The input unit 20 may include a first n-type metal oxide semiconductor (NMOS) transistor 21 and a second NMOS transistor 22. The current mirror 10 may include a first p-type metal oxide semiconductor (PMOS) transistor 11 and a second PMOS transistor 12.

The first NMOS transistor 21 may be turned ON when an input signal, input at the input port 1, transitions from a low state to a high state. Accordingly, a first node 3 may be connected to a ground voltage GND, so that the first PMOS transistor 11 and the second PMOS transistor 12 may be turned ON.

Further, the output port 9 and a second node 4 may be pulled-up to a source voltage VDDH. However, a current path 25 may exist from the source voltage VDDH to the ground voltage GND via the first PMOS transistor 11 and the second NMOS transistor 21 when the first PMOS transistor 11 is turned ON. Thus, this configuration may cause problems, e.g., power loss.

FIG. 2 illustrates a circuit diagram of a second level shifter 200 blocking the current path 25 of the first level shifter 100 in FIG. 1.

Referring to FIG. 2, the second level shifter 200 may include an input port 30, an output port 80, a switch module 40, a current mirror 50, a voltage maintaining unit 60 and an inverter 35.

The switch module 40 may include a first NMOS transistor 41 and a second NMOS transistor 42. The current mirror 50 may include a first PMOS transistor 51 and a second PMOS transistor 52. The voltage maintaining unit 60 may include a control circuit 70 and a third NMOS transistor 65.

The first NMOS transistor 41 may be turned ON when an input signal, input at the input port 30, transitions from a low state to a high state. A third node 43 may be connected to a ground voltage GND when the third NMOS transistor 65 is turned ON. The output port 80 may be pulled-up to a source voltage VDDH when the first PMOS transistor 51 and the second PMOS transistor 52 are turned ON. The current path 25 (as shown in FIG. 1) may exist through a source that may correspond to the source voltage VDDH, the first PMOS transistor 51, the third NMOS transistor 65, the first NMOS transistor 41, and a ground (corresponding to the ground voltage GND). However, the third NMOS transistor 65 may be turned OFF by an inverter 71 because the output port 80 and a second node 44, which may be connected to each other, may be pulled-up to the source voltage VDDH. As a result, the current path 25 may be blocked.

The output port 80 may be pulled-up to the source voltage VDDH because a third PMOS transistor 72 may be turned ON. However, a driving capacity at the output port 80 may be lowered because the inverter 71 may be operated by an output voltage at the output port 80, and therefore, the second level shifter 200 may be inefficient, i.e., may not function at low power.

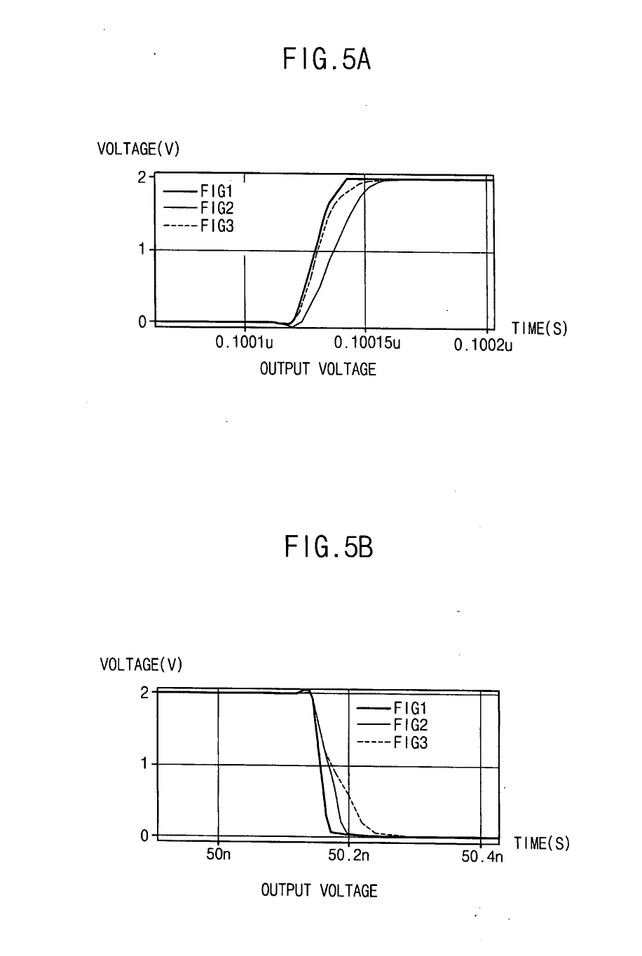

FIG. 3 illustrates a circuit diagram of a low power level shifter 300 according to an example embodiment. FIG. 4 illustrates an input voltage level of an input signal VI and an output voltage level of an output signal VO in the low power level shifter 300 according to an example embodiment.

Referring to FIG. 3, the low power level shifter 300 may include an input unit 120, a pull-down driving unit 130, a pull-up driving unit 160, a blocking unit 170, and an inverter 140. It should be appreciated that other elements and/or devices may be incorporated in the second level shifter 300.

The input unit 120 may include a first NMOS transistor MN1, and the pull-down driving unit 130 may include a second NMOS transistor MN2. The blocking unit 170 may include a first PMOS transistor MP1 and a second PMOS transistor MP2, and the pull-up driving unit 160 may include a third PMOS transistor MP3 and a fourth PMOS transistor MP4.

A gate of the first NMOS transistor MN1 may be connected to an input port 30, and the inverter 140 may be connected between the input port 30 and a gate of the second NMOS transistor MN2. A source of the first NMOS transistor MN1 and a source of the second NMOS transistor MN2 may be commonly connected to a second voltage VSS. A drain of the first NMOS transistor MN1 may be connected to a drain of the first PMOS transistor MP1. A drain of the second NMOS transistor MN2 may be connected to a drain of the second PMOS transistor MP2, and the connection point may be a second node N2, which may be connected to an output port 180. A gate of the first PMOS transistor MP1 may be connected to the drain of the second PMOS transistor MP2, and a gate of the second PMOS transistor MP2 may be connected to the drain of the first PMOS transistor MP1. A source of the first PMOS transistor MP1 may be connected to a drain of the third PMOS transistor MP3, and a source of the second PMOS transistor MP2 may be connected to a source voltage VDDH. A drain of the fourth PMOS transistor MP4 may be connected to the second node N2, and a source of the fourth PMOS transistor MP4 and a source of the third PMOS transistor MP3 may be commonly connected to the source voltage VDDH. A gate of the third PMOS transistor MP3 and a gate of the fourth PMOS transistor MP4 may be commonly connected to the drain of the third PMOS transistor MP3.

An input signal VI input to the input port 30 may switch between a first voltage VDDL and the second voltage VSS. A current may flow through a first node N1 by a switching operation of the first NMOS transistor MN1 in the input unit 120 when the input signal VI is input to the input unit 120. The pull-up driving unit 160 may be mirroring the current, and may pull-up the output port 180 to the source voltage VDDH.

When the input signal VI is low and a voltage of the first node N1 is high, the second NMOS transistor MN2 may be turned ON based on the inverted input signal by the inverter 140, and may pull-down the second node N2 and the output port 180 to the second voltage VSS, which may correspond to a ground voltage. Further, the first PMOS transistor MP1 may be turned ON based on a voltage of the second node N2, and thus, a voltage of a third node N3 may be high. As a result, the pull-up driving unit 160 may not operate.

When the input signal transitions from low to high, the first node N1 may be pulled-down to the second voltage VSS, and the third node N3 may be pulled-down to the second voltage VSS because the first PMOS transistor MP1 may be turned ON. The second node N2 and the output port 180 may be pulled-up to the source voltage VDDH when the voltage at the third node N3 is low because the third PMOS transistor MP3 and the fourth PMOS transistor MP4 may be turned ON. In an example embodiment, the second PMOS transistor MP2 may be turned ON when the first node is pulled-down to the second voltage VSS. Accordingly, the first PMOS transistor MP1 may be tuned OFF. A current path generated through the third PMOS transistor MP3 by the pull-up driving unit 160 may be blocked when the first PMOS transistor MP1 is turned OFF. As a result, the output port 180 may be driven to output the output signal VO, which may correspond to the source voltage VDDH.

FIG. 5A illustrates output voltages output from the level shifters 100, 200 and 300 in FIG. 1 through FIG. 3, respectively, when the output voltages transition from low to high. FIG. 5B illustrates output voltages output from the level shifters 100, 200 and 300 in FIG. 1 through FIG. 3, respectively, when the output voltages transition from high to low. FIG. 5C illustrates operation currents that may be generated at the level shifters 100, 200 and 300 in FIG. 1 through FIG. 3, respectively, when the output voltages transition from low to high. FIG. 5D illustrates operation currents that may be generated at the level shifters 100, 200 and 300 in FIG. 1 through FIG. 3, respectively, when the output voltages transition from high to low.

A simulation that shows the output voltages and the operation currents of FIG. 5A through FIG. 5D may be performed based on a short process, e.g., 90-nano process. The operation current of the first level shifter 100 of FIG. 1 may be measured as a typical reference current of approximately 290 μA, the operation current of the second level shifter 200 of FIG. 2 may be measured at approximately 1.3 μA, and the operation current of the low power level shifter 300 of FIG. 3 may be measured at approximately 1.28 μA. Accordingly, the operation current of the lower power level shifter 300 may be approximately 250 times smaller than that of the first level shifter 100, and approximately 2% smaller than that of the second level shifter 200.

Referring to FIG. 5C and FIG. 5D, the operation current of the first level shifter 100 of FIG. 1 may be consumed by the current path during the transition of the output voltage, e.g., after the output voltage transitions from low to high, and before the output voltage transitions from high to low. Further, the operation current of the low power level shifter 300 of FIG. 3 may be the lowest of the operation currents of the level shifters when the output voltages transition from low to high or when the output voltages transition from high to low.

Example embodiments may provide a low power level shifter and a method thereof by safely performing a level shifting operation with low power by blocking a current path generated by a pull-up driving unit while a low voltage input signal is being shifted to a high voltage output signal.

In the figures, the dimensions of regions may be exaggerated for clarity of illustration. It will also be understood that when an element is referred to as being “on” another layer or substrate, it can be directly on the other element or substrate, or intervening layers may also be present. Further, it will be understood that when a layer is referred to as being “under” another element, it can be directly under, and one or more intervening elements may also be present. In addition, it will also be understood that when an element is referred to as being “between” two elements, it can be the only layer between the two elements, or one or more intervening elements may also be present. Like reference numerals refer to like elements throughout.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A low power level shifter, comprising:
an input unit configured to generate a current signal based on an input signal applied to an input port, the input signal switching between a first voltage level and a second voltage level;
a pull-down driving unit connected to an output port, and configured to pull-down the output port to the first voltage level;
a pull-up driving unit connected between a power supply voltage having a third voltage level and the output port, and configured to pull-up the output port to the third voltage level by mirroring the current signal; and
a blocking unit connected between the input unit and the pull-up driving unit, and configured to block a current path formed between the input unit and the pull-up driving unit in response to a pulling-up operation of the output port.

2. The low power level shifter as claimed in claim 1, further comprising:
an inverter configured to invert the input signal to the pull-down driving unit.

3. The low power level shifter as claimed in claim 2, wherein the inverter operates between the first voltage level and the second voltage level.

4. The low power level shifter as claimed in claim 1, wherein the input unit includes a first n-type metal oxide semiconductor (NMOS) transistor having a gate that receives the input signal, a source connected to a ground voltage corresponding to the second voltage level, and a drain connected to the blocking unit.

5. The low power level shifter as claimed in claim 4, wherein the pull-down driving unit includes a second NMOS transistor having a gate that receives the inverted input signal, a source connected to the ground voltage, and a drain connected to the output port.

6. The low power level shifter as claimed in claim 1, wherein the blocking unit includes a first p-type metal oxide semiconductor (PMOS) transistor and a second PMOS transistor to form a latch.

7. The low power level shifter as claimed in claim 6, wherein the first PMOS transistor has a gate connected to the output port and a drain of the second PMOS transistor, a source connected to the pull-up driving unit, and a drain that receives the current from a drain of a first NMOS transistor in the input unit.

8. The low power level shifter as claimed in claim 7, wherein the second PMOS transistor has a gate connected to the drain of the first PMOS transistor and receives the current from the input unit, a source connected to the source voltage, and the drain of the second PMOS transistor is connected to the output port and the gate of the first PMOS transistor.

9. The low power level shifter as claimed in claim 8, wherein the current path between the input unit and the pull-up driving unit is blocked by the first PMOS transistor.

10. The low power level shifter as claimed in claim 1, wherein the pull-up driving unit includes a current mirror having a third PMOS transistor and a fourth PMOS transistor.

11. The low power level shifter as claimed in claim 10, wherein the third PMOS transistor has a gate and a drain that are commonly connected to a gate of the fourth PMOS transistor and connected to a source of a first PMOS transistor in the blocking unit, and a source connected to the source voltage.

12. The low power level shifter as claimed in claim 11, wherein the fourth PMOS transistor including the gate is connected to the gate of the third PMOS transistor, a source is connected to the source voltage, and a drain of the fourth PMOS transistor is connected to the output port.

13. The low power level shifter as claimed in claim 1, wherein the third voltage is higher than the first voltage, and the first voltage is higher than the second voltage.

14. A low power level shifter, comprising:
a first NMOS transistor having a gate that receives an input signal;
a second NMOS transistor having a gate that receives an inverted input signal, a source connected to a ground voltage and a source of the first NMOS transistor, and a drain connected to an output port that outputs an output signal;
a first PMOS transistor having a drain that is connected to a drain of the first NMOS transistor;
a second PMOS transistor having a gate that is connected to the drain of the first PMOS transistor, and a drain connected to the output port and to a gate of the first PMOS transistor;
a third PMOS transistor having a gate and a drain that are commonly connected to the source of the first PMOS transistor, and a source connected to a source voltage; and
a fourth PMOS transistor having a gate that is connected to the gate of the third PMOS transistor, a source connected to the source voltage, and a drain connected to the output port, the second PMOS transistor has a source that is connected to the source voltage.

15. The low power level shifter as claimed in claim 14, further comprising:
an inverter connected between the gate of the first NMOS transistor and the gate of the second NMOS transistor.

16. The low power level shifter as claimed in claim 15, wherein the inverter operates between a first voltage and the ground voltage, the source voltage being higher than the first voltage.

17. The low power level shifter as claimed in claim 14, wherein the input signal switches between a first voltage and the ground voltage, and the output signal switches between the source voltage and the ground voltage.

18. The low power level shifter as claimed in claim 17, wherein the source voltage is higher than the first voltage.

19. A method of low power level shifting, comprising:
generating a current according to an input signal that switches between a first voltage and a second voltage;
pulling-down an output port to the first voltage according to an inverted input signal;
pulling-up the output port to a third voltage by mirroring the current; and
blocking a current path that is generated when the output port is pulled-up.

20. The method as claimed in claim 19, further comprising:
inverting the input signal to pull-down the output port.

21. The method as claimed in claim 20, wherein the third voltage is higher than the first voltage, and the first voltage is higher than the second voltage.
